(19) United States
(12) Patent Application Publication
(10) Pub. No.: US 2005/0017257 A1
(43) Pub. Date: Jan. 27, 2005

(54) High efficiency silicon light emitting device and modulator

(76) Inventors: Martin Andrew Green, Bronte NSW (AU); Jianhua Zhao, Coogee NSW (AU)

Correspondence Address: JOHN S. PRATT, ESQ;KILPATRICK STOCKTON, LLP, 1100 PEACHTREE STREET, ATLANTA, GA, 30309, US

(21) Appl. No.: 10/479,654

(22) PCT Filed: May 30, 2002
(86) PCT No.: PCT/AU02/00692

(30) Foreign Application Priority Data
May 30, 2001 (AU) PR 5342

(51) Int. Cl. H01L 21/00; H01L 33/00

(52) U.S. Cl. 257/98; 257/99; 438/27; 438/29

(57) ABSTRACT

The present invention provides a high performance silicon light emitting device. A method and device providing both emission and modulation from a single device is provided, with modulation of the emission characteristics being achieved by application of an electric field across the device, so as to induce quantum confined Stark effects, Franz-Keldysh effects or the like.

### TECHNICAL FIELD

The present invention relates to high efficiency silicon light emitting devices such as diodes, and to a method of designing and operating such devices.

### BACKGROUND ART

Light emitting diodes (LEDs) are an extremely common electronic device with a wide range of applications, including displays, short distance communications over fibres, opto-couplers, indicators and infrared wireless communication (including television remote controls and free space data links). LEDs typically comprise a light-emitting gallium arsenide pn junction (which emits based on direct band-to-band transitions) or may comprise GaAs₁₋ₓPₓ, with an isoelectronic dopant such as nitrogen (which emits based on impurity states in the bandgap). GaAs LEDs have been found to offer acceptable quantum efficiencies, approaching 1%, while the use of nitrogen as an isoelectronic dopant in a GaAs₁₋ₓPₓ LED can improve the quantum efficiency of the LED to over 1%.

The materials of a LED may also be chosen in order to produce light of a desirable frequency. For example, GaAs LEDs produce around 900 nm (infrared) light, GaP:ZnO LEDs produce around 650 nm (red) light, GaAs₁₋ₓPₓ LEDs produce light around the 580 nm (yellow) to 620 nm (orange) range, depending on the value of x, GaP:N LEDs produce green light, and GaN LEDs have recently been introduced to provide emission at around 400 nm (violet).

However, the use of such materials prevents integration of LEDs into silicon devices. While attempts have been made in the past to manufacture silicon LEDs, the conversion efficiency of silicon LEDs has, for most applications, been unacceptably low. Conversion efficiencies of silicon devices are usually around 0.001%, while the highest performance silicon junction devices have achieved efficiencies around 0.01%.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect the present invention provides a light emitting device with alterable emission characteristics, the device comprising:
a light emitting portion comprising a pn junction for emission of light by application of current to the pn junction; and
means for applying an electric field across the light emitting portion in order to alter a light emission characteristic of the light-emitting portion.

By providing a light emitting device with alterable emission characteristics, the present invention enables both generation and modulation of a light signal by a single device. This may be important in devices where physical size is a consideration, for example when integrating such devices in an integrated circuit. Furthermore, by alleviating physical size concerns in this manner, the present invention may allow the light emitting portion of such a device to be formed of materials having lesser quantum efficiency while forming the device of larger size so as to maintain a sufficient intensity output. For instance, the light emitting portion and pn junction of such devices may be formed of silicon. While Si is of lower quantum efficiency than GaAs, a larger light emitting Si device may provide similar light intensity as a relatively smaller GaAs device. Further, Si is a particularly suitable material for integration into silicon integrated circuits. The light emitting portion of the device may alternatively be formed of SiGe or other materials.

The light emitting portion of the device of the first aspect of the present invention preferably comprises a thin layer which is thin enough for quantum confinement effects to occur. For example the thin layer may comprise a quantum well. In such embodiments, the means for applying the electric field is preferably arranged such that the electric field is applied across the thin layer substantially normal to a plane defined by the layer. In such an orientation the electric field enables significant quantum confined Stark effect modulation of absorption and emission properties of the thin silicon layer, thus enabling modulation of peak emission wavelength and emission intensity at a given wavelength. However, modulation of the light emission characteristics of the light emitting portion may also be achieved by application of an electric field across the light emitting portion in a direction other than substantially normal to the plane. The thin layer may comprise a crystalline silicon layer comprising the quantum well.

Alternatively, the light emitting portion may comprise a layer which has a thickness greater than a maximum thickness which can achieve quantum confined Stark effects. In such embodiments, the application of the electric field may nevertheless cause modulation of the emission characteristics of the light emitting portion due to the Franz-Keldysh effect.

According to a second aspect the present invention provides a method of altering light emissions from a light emitting diode, the method comprising the step of:
applying an electric field across the light emitting diode so as to alter light emission characteristics of the diode.

To date, light modulation schemes have often been comprised of two separate components, namely a light source and a modulator. Light is continuously generated by the light source, such as a light emitting diode, and then passed through a modulator which is controlled so as to either allow the light to continue or to prevent further passage of the light. Such systems require a separate physical area for each of the two components, for example increasing chip space demands. Alternatively, an LED may be used as a modulator by simply turning the pn junction on and off, however the recombination time of the LED material limits application of such modulation to low frequencies, for example less than MHz.

However, by applying an electric field across an LED in order to exploit quantum confined Stark effects, Franz-Keldysh effects or the like so as to alter emission characteristics of the diode, the present invention avoids the need for a separate modulator and hence the need for separate chip space, and also uses a modulation technique which permits very high switching rates for example tens or hundreds of GHz.

Such a technique may be particularly useful in silicon diode applications, in which high quality silicon (with a relatively large recombination time) is desired to be used, and in which a relatively large physical bulk of silicon may be required in order to produce a given power output. By alleviating the chip-space issues involved with having a separate modulator, and by avoiding the trade-off of recombination time against switching rate, the present invention may thus provide for silicon LEDs with high quality (and high recombination time) material providing appropriate output intensity levels, yet allowing for high speed switching.

Accordingly, in preferred embodiments of the present invention, the light emitting portion of the device is formed of a material having high excited carrier lifetimes, in order to assist in reducing bulk recombination.

Preferably, the light emitting diode comprises a thin layer quantum well, wherein application of an electric field to the quantum well results in an alteration of the emission characteristics of the well due to the quantum confined Stark effect. In such embodiments, the electric field is preferably applied in a direction substantially normal to a plane defined by the thin layer.

Alternatively, even where the light emitting diode is thicker than required for quantum confinement, application of an appropriate electric field across the diode may generate sufficient alteration in the emission characteristics of the diode due to the Franz-Keldysh effect, thus providing measurable modulation of the light emissions of the device.

The light emitting diode may be formed of crystalline silicon, GaAs or other materials appropriate for operation as a light emitting diode and exhibiting electroabsorption, that is, absorption and emission characteristics which vary with applied electric field.

In embodiments in which the light emitting portion of the device is formed of a thin layer of crystalline silicon exhibiting quantum confinement, the device is preferably a waveguide edge emitting device. In such devices, the waveguide is preferably formed by lower refractive index layers such as SiO₂ positioned either side of the thin silicon layer such that light generated within the thin silicon layer travels within the silicon layer to emerge laterally from the silicon layer.

Such embodiments allow for summation of the light intensity along the waveguide, and may thus produce an output light intensity at an appropriate level despite the relatively low intrinsic quantum efficiency of silicon. In such embodiments, the largest dimensions of the device are preferably kept smaller than a typical diffusion length of the semiconductor material. Of course, where the silicon layer is thin enough to exhibit quantum confinement effects, the silicon layer thickness will be significantly less than the diffusion length. For example, to exhibit quantum confinement effects, the silicon layer is likely to be 20 nm thick at most, and in some embodiments may be around 2 nm. The thickness of the silicon layer may be chosen in order to optimise the performance of the waveguide at the desired frequency of emission.

It has been realised that both bulk and integrated edge emitting silicon light emitting devices may be formed, as the increase in dark saturation current density associated with edge emitting structures is to some extent offset by shorter emission wavelengths and higher probability of occupation of photon states at such energies. Embodiments of the present invention may comprise selected oxide and/or doping regions for controlling surface contributions to the dark saturation current density. Further, embodiments of the invention may be particularly advantageous in integrating silicon light emitting devices into integrated circuits.

Alternatively the device may be a surface emitting device in bulk or integrated form, which may comprise transparent layers between the light emitting portion of the device and the region into which the light is to be emitted. For example, a surface emitting device may comprise a transparent silicon oxide layer over the light emitting portion, and a transparent electrode over the silicon oxide layer, for applying the electric field. Alternatively a non-transparent electrode for applying the electric field may be positioned sparsely over the light emitting portion; such as in a grid pattern, so as to limit the shading of the light emitting portion by the electrode.

Preferably, contacts provided for biasing the p and n regions of the pn junction are situated at opposed lateral edges of the emission layer. This feature is preferable both where the layer is very thin such as in integrated form, and in cases where the layer is relatively thick so as to act as a bulk region emitting device. In such embodiments, the p and n contacts do not shade the light emitting region of the device, and thus will provide improved emission efficiency over arrangements where the p or n contact is positioned over the emitting region of the device. Preferably, a heavily doped p+ region is provided close to the metal p contact, and a heavily doped n+ region is provided close to the metal n contact. Further, a region of n+ or n+/intrinsic amorphous silicon may be provided instead of the n+ region, and a p+ or p+/intrinsic amorphous silicon region may be provided instead of the p+ region.

Such regions of amorphous silicon can maintain good conduction into the metal conductor and also provide a good surface interface.

The layer below the silicon quantum well layer may be formed of a reflective material such that light emitted away from the intended direction of emission is reflected towards the intended direction of emission. For instance, a dielectric/metal reflecting layer combination may be provided in order to internally reflect light from a surface from which emission is not desired. Such a reflector preferably has a high reflectance in order to reduce metal absorption losses.

Embodiments of the present invention which exploit the quantum confined Stark effect (QCSE) and field controlled modulation or switching, have the potential to be very useful because the QCSE has application at very high frequencies as there is no intrinsic limitations at least up to picosecond switching intervals (tens of GHz). In fact, any switching limitation is likely to be in the capacitance and resistance of the external voltage supply circuitry. To the contrary, the switching rate of normal LEDs is limited by the recombination time of the bulk material, which limits the switching applications of high performance silicon LEDs to a few hundred kHz. High speed (but lower efficiency) LEDs with introduced impurities have a reduced recombination time and can provide switching rates of up to many Mb/s, however this is still significantly slower than may be offered by quantum confined Stark effect switching.

In preferred embodiments of the first and second aspects of the invention, an anti-reflective coating over a surface from which the device emits light is provided in order to increase emissivity at desired frequencies.

According to a third aspect the present invention resides in a silicon light emitting device formed using a silicon wafer substrate and comprising metal contacts, wherein the metal contacts are isolated from the substrate by an insulating dielectric apart from small local contact areas. Isolation of metal contacts from the substrate assists in reducing metal-semiconductor recombination.

For instance, in embodiments of the first and second aspects of the invention, the metal contacts are preferably formed after a layer of silicon oxide has been formed over the substrate, thereby isolating the metal contacts from the substrate.

According to a fourth aspect the present invention resides in a silicon light emitting device comprising means for controlling carrier concentrations in surface regions to minimise surface recombination. The means for controlling carrier concentrations may comprise regions of the silicon device proximal to the surfaces having controlled doping levels. Alternatively or additionally the means for controlling carrier concentrations may comprise electrostatic means such as overlying heterostructures.

Preferred embodiments of the fourth aspect of the invention may have a device thickness which is a significant fraction of a diffusion length. Increasing the device thickness results in an approximately linear increase in emitted light output, while causing only small increases in the diode dark saturation current density, which is largely dependent on surface recombination rather than on device thickness. At thicknesses greater than a diffusion length, performance will start to degrade. However, embodiments of the invention may have multiple layers forming a multiple junction device, providing an overall device thickness of greater than a diffusion length. Of course, in embodiments in which the device is of a thickness to support quantum confinement effects, the device thickness will be significantly less than a diffusion length.

According to a fifth aspect the present invention resides in a light emitting silicon device comprising a bulk region being only relatively lightly doped, and wherein the device comprises only relatively small amounts of relatively heavily doped silicon.

According to a sixth aspect, the present invention resides in a method of fabricating a silicon light emitting device comprising metal contacts, the method comprising the step of minimising the area of the metal contacts. Minimising the area of the metal contacts minimises surface recombination in the vicinity of the metal contacts. For example, in embodiments of the first and second aspects of the invention in which the light emitting portion of the device acts as a waveguide, the p and n metal contacts may comprise small metal contacts positioned only at a limited number of locations along the lateral edges of the light emitting portion. Thus, as carriers pass along the waveguide, surface recombination will be limited due to the limited number of positions and limited total surface area of the respective contacts.

According to a seventh aspect, the present invention resides in a method of fabricating a silicon light emitting device comprising the step of passivating non-contacted surface areas of the device. The step of passivating may comprise forming a heterostructure over the surface, such as a surface oxide layer. Alternatively or additionally, the step of passivating may comprise deposition of a polycrystalline layer, a microcrystalline layer and/or an amorphous silicon layer, or the like.

Preferred embodiments of the seventh aspect of the invention provide a sufficiently high level of surface passivation to allow quasi-fermi potentials to be approximately constant throughout the device. Thus, in embodiments of the first and second aspects of the invention in which the light emitting portion acts as a waveguide with n and p contacts only at a small number of spaced locations along the lateral edges of the waveguide, the edge portion of the waveguide between each contact is preferably passivated by providing a transparent dielectric layer such as silicon oxide over the light emitting portion. Similarly, the light emitting portion is preferably formed over a passivation layer, and a passivation layer is preferably formed over the light emitting portion.

According to an eighth aspect, the present invention resides in a method of fabricating a silicon light emitting device comprising the step of introducing silicon defects to enhance sub-bandgap absorption. Of course, enhancement of sub-bandgap absorption corresponds to enhanced sub-bandgap emission. The step of introducing silicon defects may comprise introducing defects to produce energy states in the bandgap corresponding to a desired emission wavelength. For example, emissions at 1.55 micron may be desirable in optical communication systems, and the introduction of appropriate silicon defects may provide a silicon device having appropriate emission wavelengths, and importantly, relatively high emission efficiencies at such wavelengths.

Preferably, the introduced silicon defects of embodiments of the eighth aspect of the invention are such that carriers from the band that is closest in energy to the defect level energy make rapid transitions to and from the defect energy, while transitions to and from the other band are relatively slow and radiatively efficient. Such embodiments preferably ensure that occupancy of the defect is governed by the occupancy of the nearer band and that radiative emission to the other band will increase exponentially with voltage, as for band-to-band emission. Introduced defects may comprise Ge from Group IV of the periodic table, or dopants from Groups III or V. In particular, the introduced defects may comprise dopants such as indium and thallium so as to give rise to states relatively deeply within the bandgap, or the introduced defects may comprise defects that more tightly bind electrons such as rare earth metals, for example Er or Yb. Er may be particularly appropriate in optical communications applications, as it offers an absorption peak close to 1.55 microns. The introduced defects may comprise combinations of such dopants, and further, combinations of rare earth dopants may increase the efficiency of absorption processes. Additionally or alternatively, the introduced defects may comprise defects such as dislocations.

According to a ninth aspect the present invention resides in a silicon light emitting device comprising an emitting surface having geometry for directing emissions in a predetermined direction. Embodiments of the ninth aspect of the invention may be particularly advantageous in optical communications systems. The emitting surface geometry may be implemented by bevelling of the emitting surface or by using a periodic structure to produce a diffraction effect. In preferred embodiments of the ninth aspect, the surface geometry will also serve to enhance emissions from the device.

According to a tenth aspect the present invention resides in a silicon light emitting device with surface geometry adapted to control the passage of light in the device so as to improve absorption. The surface geometry is preferably adapted so as to improve the passage of long wavelength light, for instance light of wavelength longer than 1000 nm.

Preferred embodiments of the tenth aspect of the invention have a surface geometry created by texturing one or more surfaces of the device. The textured surface geometry may comprise (111) equivalent crystallographic planes present in a (100) orientated wafer surface plane, exposed for example by anisotropic etching. Further embodiments of the tenth aspect of the invention may comprise surface geometry having crystallographic features in distinct locations. Such locations may be controlled by photolithography, or may arise through random nucleation.

In embodiments of the tenth aspect of the invention where the light emitting device is required to have emissions concentrated at a particular range of energies or emission angles, the device may have surface geometry adapted to maximise absorptance (and hence emittance) at those particular energies or emission angles.

According to an eleventh aspect the present invention resides in a method of design of a silicon light emitting diode, comprising the step of:
designing a silicon device having high light absorption, for reverse operation as a light emitting diode.

It has now been realised that techniques and features which have been developed in relation to silicon devices having high light absorption, such as silicon solar cells, are often applicable in design of a relatively high efficiency silicon light emitting device, such as a silicon LED. Accordingly, it is envisaged that significant improvements in silicon LED efficiency may be achieved by use of absorption enhancement techniques in emission optimisation.

According to a twelfth aspect, the present invention provides a light modulator comprising:
a thin layer of silicon exhibiting quantum confinement effects, to be positioned in the path of light to be modulated; and
means to apply an electric field across the thin silicon layer so as to alter the bandgap of the silicon layer by way of the quantum confined Stark effect, thus controlling whether light is absorbed by the silicon layer or transmitted through the silicon layer.

According to a thirteenth aspect, the present invention provides a method of modulating light, the method comprising the steps of:
positioning a thin layer of silicon in the path of the light, the silicon layer exhibiting quantum confinement effects; and
applying an electric field across the thin silicon layer so as to alter the bandgap of the silicon layer by way of the quantum confined Stark effect, thus controlling whether light is absorbed by the silicon layer or transmitted through the silicon layer.

It has now been realised that quantum confined structures may be formed of silicon. Thus, the twelfth and thirteenth aspects of the invention provide for modulation devices which utilise quantum confinement effects in modulating light passing through the thin silicon layer. As the quantum confined Stark effect causes an alteration of the bandgap of the silicon upon application of an electric field, such devices will be of application when modulating light of particular frequencies. Such frequencies will be those which are either absorbed by the silicon or transmitted through the silicon, depending on whether the electric field is applied. Further, the twelfth and thirteenth aspects of the invention may be particularly advantageous in providing for convenient integration of a silicon quantum confined Stark effect light modulating device onto a silicon integrated circuit, whether in bulk or integrated form.

Preferred embodiments of the invention may comprise features of two or more of the first to thirteenth aspects of the invention as previously described.

The silicon light emitting device of any of the first to thirteenth aspects may be a silicon light emitting diode, an optical coupler or the like.

### BRIEF DESCRIPTION OF THE DRAWINGS

By way of example only, preferred embodiments of the invention are described with reference to the accompanying drawings, in which:

FIG. 1 is an illustrative side view of a side-emitting silicon structure suitable for integration using silicon on insulator (SOI) technology;

FIG. 2 is an illustrative side view of an alternate side-emitting silicon structure with a rib structure to provide waveguiding in thicker silicon layers based on SOI technology;

FIG. 3 illustrates the quantum confined Stark effect;

FIG. 4 illustrates an edge-emitting device providing both emission and modulation suitable for integration using SOI technology;

FIG. 5 is a schematic of a high efficiency silicon light emitting diode fabricated into a bulk silicon wafer in accordance with the present invention;

FIG. 6 is a graph of External Quantum Efficiency (EQE) and power conversion efficiency (PCE) for the particular embodiment of the present invention shown in FIG. 5;

FIG. 7 is a graph showing electroluminescence spectra for textured, planar and baseline silicon diodes of FIG. 5 under 130 mA bias current at 298K;

FIG. 10 is a graph of optical coupling performance using a silicon emitter and silicon detector;

FIG. 11 illustrates a parallel junction multilayer silicon light emitting device;

FIG. 12 illustrates a silicon light emitting device with edge emitting geometry;

FIG. 13 illustrates an edge emitting silicon device with bevelled edges;

FIGS. 14a, 14b and 14c illustrate alternate geometries for silicon light emitting devices; and

FIGS. 15a and 15b are side views of silicon light emitting devices incorporated onto microchips.

### DESCRIPTION OF THE INVENTION

An edge emitting silicon device 10 in accordance with the present invention is shown in FIG. 1. This device makes use of a buried dielectric silicon oxide layer 12 that is an easily obtainable feature when using silicon-on-insulator (SOI) technology. The advantage of this approach is the small device cross sections that are possible, the excellent light confinement prospects possible due to the high refractive index step between the silicon layer 11 and the dielectric layers 12 and 13, generally silicon dioxide, and the suitability for incorporation into standard silicon integrated circuits.

If the top silicon layer 11 is less than about 200 nm thick, as is normally the case for SOI technology, only a single optical waveguide mode can be supported by the layer 11 shown in FIG. 1 in the longitudinal direction into the page (ie normal to the page). Modern lithographic methods allow similar control over lateral dimensions. Minority carrier diffusion lengths in the n⁺ doped region 14 and p⁺ doped region 15 are considerably less than 1 micron at the required doping levels meaning that only a small portion of these regions will be electronically active. Any regions larger in extent than this will merely act as electrical contacting material to respective metal contacts 16 and 17. For best performance, the buried oxide (BOX) layer 12 will be reasonably thick to prevent optical coupling to the substrate. The refractive index decreases in the doped region due to free carriers would help to confine the propagating wave to the regions of high gain.

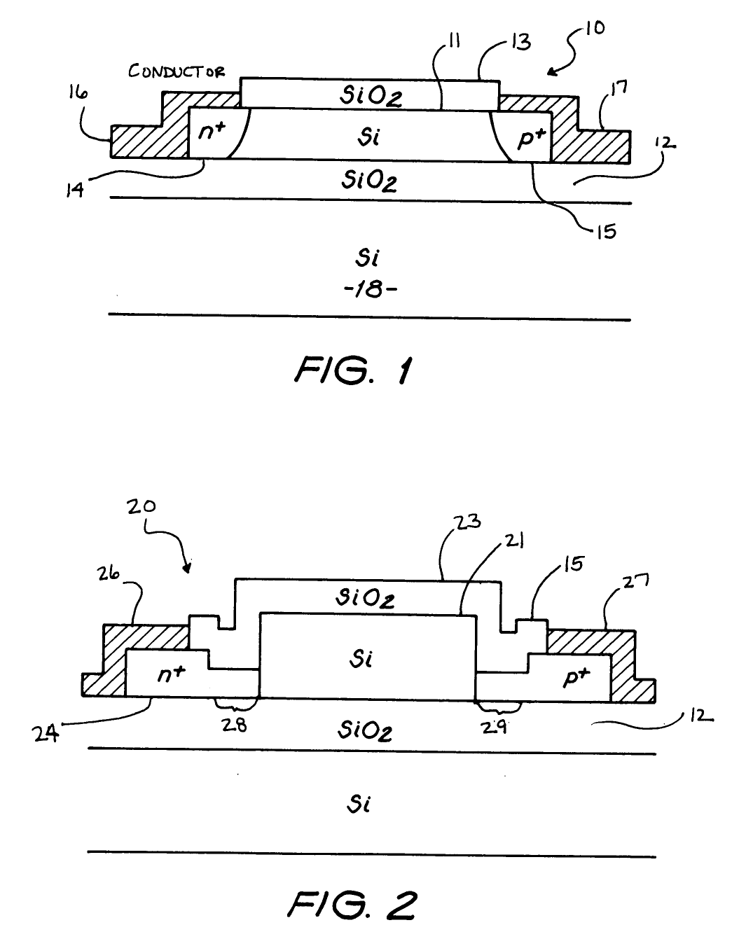

A variation upon this approach is shown in FIG. 2. The use of a rib waveguide approach would allow single mode optical wave propagation in the direction normal to the page even if the thickness of silicon layer 21 were appreciably larger than layer 11 mentioned above in respect of FIG. 1. An additional advantage would be that it is possible to thin the SOI layer in the doped regions (indicated at 28 and 29 in FIG. 2) to thicknesses below 10 nm, where electron confinement increases the bandgap. This provides a method for reducing recombination in these areas compared to that in the bulk.

The output of such devices may be modulated. The technique of modulation of devices such as shown in FIG. 1, is based on the quantum-confined Stark effect, visually described in FIG. 3. Essentially, an electric field applied perpendicularly to a quantum well lowers the threshold for light absorption. The well shown on the left has no applied field, and has a bandgap hf₁. The well shown on the right is in the presence of an electric field, which alters the bandgap to hf₂. Thus, such a well can quickly be made either transparent or opaque to emitted light by modulating the electric field across it.

Accordingly, where the silicon layer 11 of the device shown in FIG. 1 is sufficiently thin and acts as a quantum well, application of an appropriate electric field perpendicular to the layer allows modulation of the emissions of the device 10.

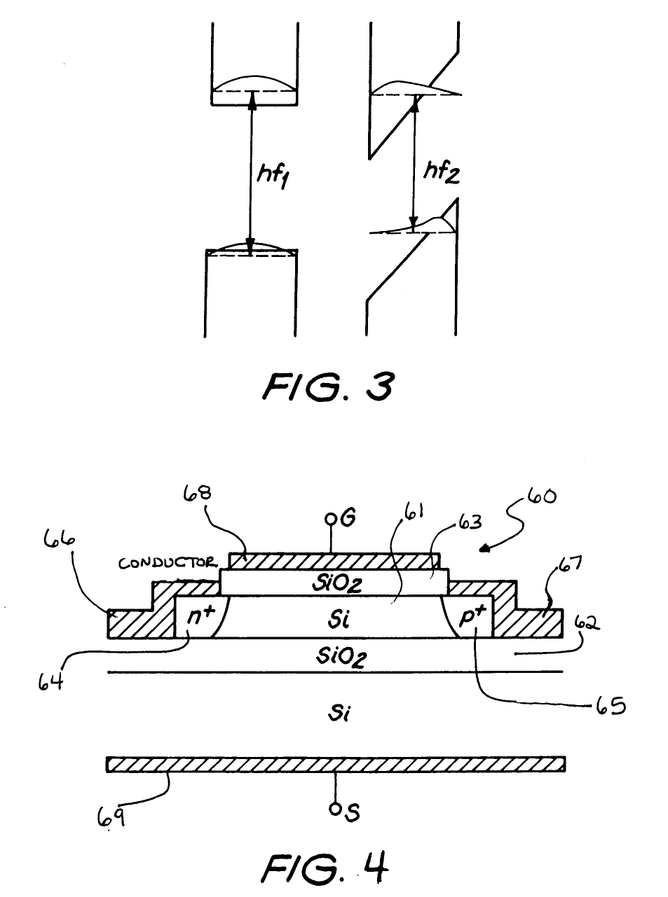

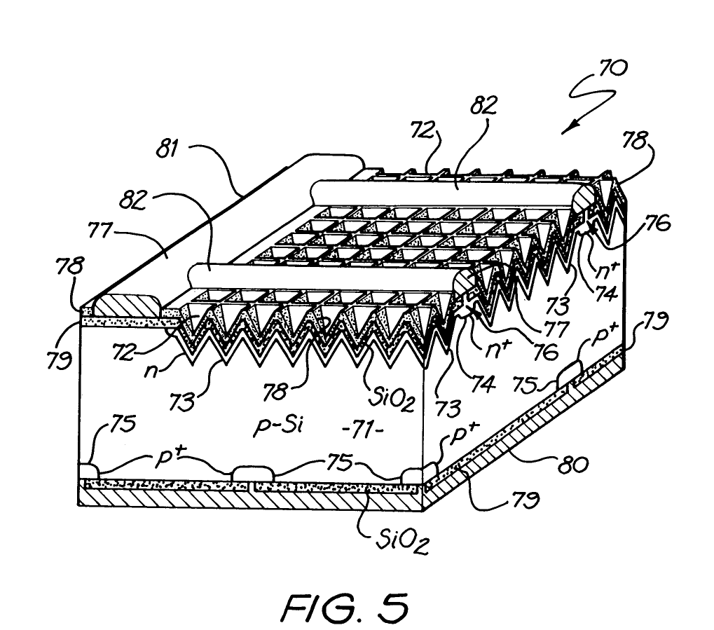

There is evidence that these quantum well devices are more strongly absorbing than a comparable thickness of bulk silicon, possibly as a result of relaxation of momentum conservation requirements during absorption due to confinement. However, considerable chip area may be required for integration in the traditional way. Accordingly, the device structure 60 as shown in FIG. 4 has been conceived, where light emission and modulation are combined in the one device.

This device includes a thin quantum well silicon layer 61, silicon oxide dielectric layers 62 and 63, n+ doped region 64 and p+ doped region 65, and metal conductor contacts 66 and 67. Device 60 further includes two contacts 68 and 69, respectively dubbed a gate and a source, for application of an electric field perpendicularly to the plane of the layer 61, and dielectrically isolated from the silicon layer 61. (Conveniently and interestingly, the device 61 has a structure similar to a standard MOSFET but with the polarity of the drain reversed). By applying voltage to the gate 68 the wavelength of peak emission and the emission intensity of the device 61 at this wavelength can be varied, providing a new, compact modulation approach.

The suggestion of the use of the Stark effect to modulate silicon LED output is new, since it is unusual to think of the use of silicon in quantum-confined structures, not least for the reason that it is difficult to prepare high quality silicon quantum wells since silicon does not grow epitaxially on other common semiconductor material. The structure of FIG. 4 would further be very easy to integrate into silicon chips due to its physical similarity to silicon MOSFETs. By changing the voltage on the gate 68, it is possible for the device output to be varied.

Furthermore, the silicon layer 61 may even be thicker than required for quantum-confinement but it would still be possible to modulate the output by the Franz-Keldysh effect.

A quest over the last several decades has been to find approaches that allow significant light emission from silicon to allow complete optoelectronic systems to be integrated into silicon microchips. However, silicon's indirect bandgap reduces the prospects for converting electrons flowing in silicon p-n junction diodes to emitted photons. This has made previous approaches to producing high efficiency silicon light emitters largely unsuccessful. A new class of silicon light emitting diode is described that displays high light emission efficiency, comparable to that of all but the best compound semiconductor devices. The improvement arises from increased device absorption and hence emission properties obtained by noting that a generalised form of Kirchhoff's Law applies to light emission from such devices. By patterning the device geometry to enhance light absorption and by minimising parasitic non-radiative recombination in the experimental devices greatly increased performance is demonstrated.

The improved devices take advantage of normally weak sub-bandgap light emission from silicon. Generation of this light requires the emission of one or more phonons as well as the photon.

The new devices exploit silicon's strengths as an electronic material to offset the disadvantage of an indirect bandgap. The new devices include all or some of the following features:
the use of surface geometry to control light passage within the diode to increase absorption and hence emission at long wavelengths;
the use of efficient dielectric metal reflector combinations which recycle light that would otherwise be emitted from surfaces from which emission is not desired;
the use of antireflection coatings to increase emissivity at desired emission wavelengths;
the reduction of parasitic optical absorption in the device by keeping doping in the bulk region low and volume of heavily doped material in the device small;
incorporation of selected defects into the device to enhance sub-bandgap absorption and hence emission;
low area of metal contact to the device to minimise surface recombination in contact areas;
passivation of non-contacted surface areas of the device by the use of heterostructures such as formed by surface oxide layers or by the deposition of polycrystalline, microcrystalline or amorphous silicon or related layers;
the control of carrier concentrations in surface regions to ensure low recombination in both contacted and non-contacted areas by measures such as doping or by electrostatic means such as by the use of overlying heterostructures;
the reduction of bulk recombination in the device by the maintenance of high excited carrier lifetimes in the device; and
isolation of metal contacts from the substrate where possible to reduce metal-semiconductor recombination.

Both surface and edge emitting diode configurations are feasible with this approach.

FIG. 5 shows a surface emitting device made in accordance with the present invention. For best performance, this device is fabricated from a high carrier lifetime silicon wafer, such as prepared by the float-zone or magnetically confined Czochralski crystal growth approaches. One or both surfaces are textured preferably using anisotropic etching to expose (111 ) equivalent crystallographic planes in the originally (100) orientated wafer surface plane. Locations of crystallographic features can be controlled using photolithography to define the location of these features or they can be nucleated randomly. Devices are diffused selectively on both surfaces using photolithography to define the location of diffused regions. Electrical contact is made to diffused regions through contact holes or slots etched through an oxide layer which otherwise completely enshrouds the device. Metal patterning and alignment is achieved using photolithographic techniques. Finally, an antireflection coating is deposited designed to minimise reflection at the desired emission wavelengths.

With the high levels of surface passivation and good carrier lifetimes in the device, carrier quasi-fermi potentials are approximately constant throughout the device over a reasonable range of operation conditions. As taught by Würfel (P. Würfel, “The Chemical Potential or Radiation”, J. Phys. C: Solid State Phys., 15 (1982) 3967-3985), this imparts a chemical potential to photons generated by recombination within the device equal to qV where q is the electronic charge and V the voltage across the device. The photon emission rate from any surface per unit area, solid angle Ω, and energy E is given by a modified form of Plankian emission expression:

$$\dot{n} dEd Ω = \frac{2}{{h}^{3} {c}^{2}} A ( E ) {E}^{2} {f}_{pt} dEd Ω \qquad ( 1 )$$

where h, c and k are well known physical constants and T is device temperature. A(E) is the device absorptance or equivalently, its emittance which may depend on incident angle, fₚₜ is the equilibrium phonon occupation probability function which is given by:

$${f}_{pt} = \frac{{α}_{VC} {ⅇ}^{- ( E - qV ) / kT} + {α}_{FC} {ⅇ}^{- E / kT}}{{α}_{VC} [ 1 - {ⅇ}^{- ( E - qV ) / kT} ] + {α}_{FC} [ 1 - {ⅇ}^{- E / kT} ]} , \qquad ( 2 )$$

where α_{VC} is the absorption coefficient for band to band absorption, and α_{FC} is the effective total parasitic absorption coefficient which includes free carrier absorption and absorption in metal contacts due to less than perfect reflectance. Alternatively, α_{FC} represents only free carrier and other parasitic bulk absorption processes if A(E) is that part of the absorptance attributable to absorption in bulk regions. This latter formulation shows that the requirement for high light emission rates is a high ratio of band to band absorption compared to parasitic bulk absorption with most of the device absorptance due to bulk processes.

Using this expression, features required for desired emission properties can be determined. For emission concentrated at a particular range of energies or emission angles, the absorptance needs to be strongly peaked for incident light of the desired energy or angle of incidence. To maximise overall light emittance, absorptance needs to be as large as possible over the range of emission energies and angles with parasitic optical absorptance within the device as small as possible. Surface geometries can be used to enhance this outcome.

An approximate expression for the absorptance A when incident light has a large pathlength P in the device induced by the surface geometry is:

$$A = \frac{( 1 - {R}_{f} ) α P}{( 1 - {R}_{f} ) + α P} \qquad ( 3 )$$

where R_{f} is the reflectance from the front surface of the device and α is the total absorption coefficient. When the large pathlength is obtained by randomising light direction in the device, P=4n²W where n is the refractive index for the photon energy of interest and W is the device thickness. Low R_{f} and large W will increase light emission. The 4n² factor is a pathlength enhancement factor due to light randomisation and highlights the importance of randomisation as a way of obtaining high A values at long wavelengths.

Losses due to metal absorption can be included into the analysis by assigning a distributed absorption coefficient as previously mentioned. For example, for the rear surface reflector of FIG. 5, an absorption coefficient equal to (−In (R_{b})/4W) could be assigned to accommodate the associated optical losses where R_{b} is the rear reflectance (since the average ray has a pathlength of 4W across the device and back).

The conversion efficiency of the device is the ratio of the optical power emitted to the electrical power supplied to the diode. Ideally, the current-voltage (I-V) relationship of the diode is given by the ideal-diode law:
I=I₀₁ [exp(qV/kT)−1] (4)
where I₀₁ is the dark saturation current of the diode and kT/q is the “thermal voltage” equal to 25.852 meV when the temperature, T, equals 300 K. For large V, this equation predicts an approximately exponential increase in current with increasing voltage. Equations (1) and (2) predict a similar increase in the emitted light intensity. Hence, over a certain current range, the ratio of emitted light intensity to diode current stays approximately constant. This is measured as the external quantum efficiency (EQE), the ratio of the number of emitted photons to the number of electrons supplied as current to the diode. Values above 0.1% for this parameter have been demonstrated for the first time for silicon diodes with the new approach. The power conversion efficiency is the ratio of the power in the emitted light to the electrical power supplied to the diode. For the present high performance silicon devices, this reaches an optimum at low voltages and is higher than the EQE, reaching values above 1% for the first time for silicon at temperatures not far below room temperature.

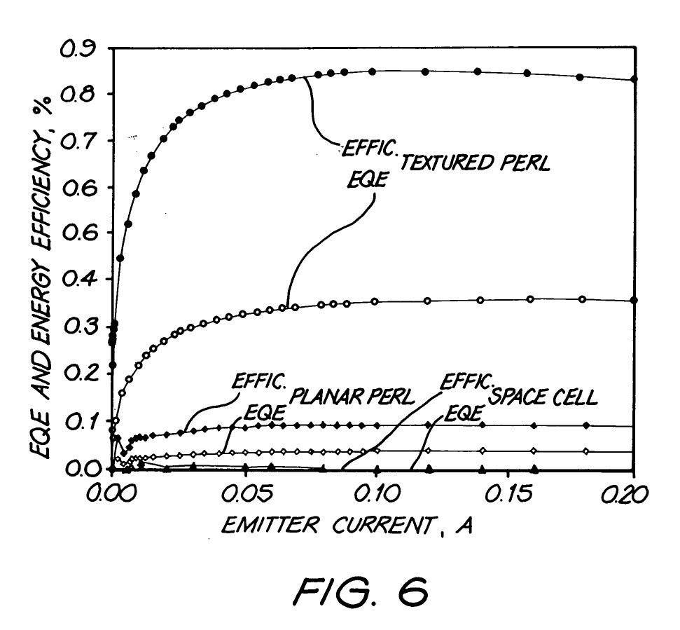

FIG. 6 shows the measured power and quantum conversion efficiencies for three devices. The first, corresponding to very low efficiencies is what is typically obtained with representative high quality silicon devices, in this case a high performance commercial silicon space cell. Both quantum and power conversion efficiencies are low (0.001-0.01% range, as typically reported for silicon devices). The intermediate set of curves shows the performance of a device similar to that of FIG. 5 but without the surface features that increase absorbency and emittance. The improved electronic features increase efficiency to values higher than previously reported (0.01 to 0.1% range), by reducing the diode dark saturation current density. Values as low as 30-70 fA/cm² range at 300 K are possible with the techniques described, much lower than traditional diode fabrication approaches.

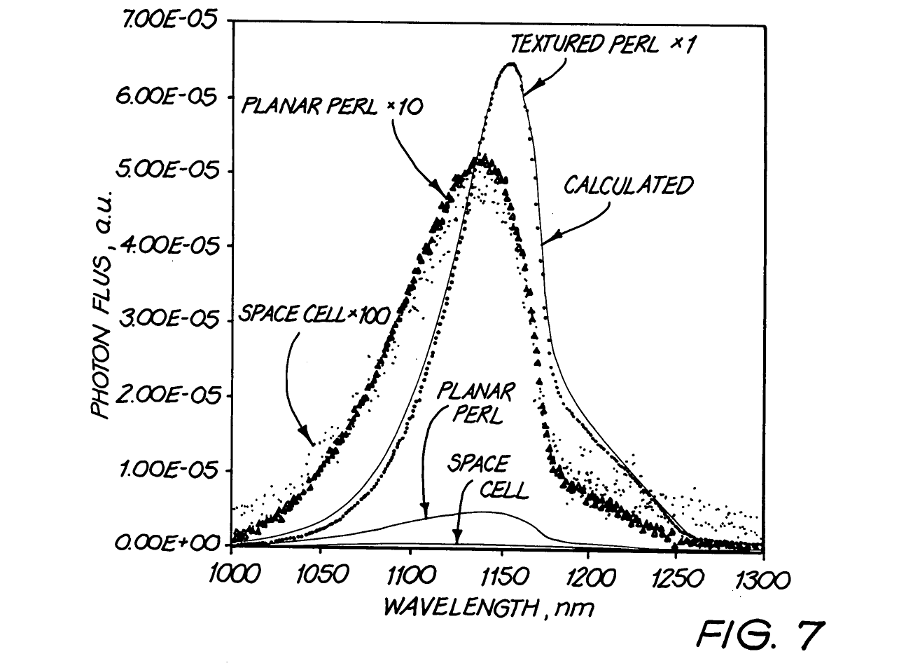

The third and highest efficiency set of curves correspond to the device that includes surface texturing. The efficiency of this device peaks at close to 1%, exceeding this value at slightly lower temperature. FIG. 7 compares the measured intensity of photon emission as a function of device wavelength confirming the results of FIG. 6 as well as the previous theory.

One possible application of the new devices is as an optical coupler. Since features of the device that make it a good emitter of light also make it a good absorber, similar devices can be used for both emission and detection functions. FIG. 8 shows measured results for such a combination. Detector current is approximately 500 times smaller than emitter current at the present stage of development. This is already a practical value for use of such coupling with improvements as described expected to give higher values in the future.

One way of improving emitter efficiency is by increasing the device thickness. Since surface recombination contributes a large component to I₀₁, the value of I₀₁, will increase only slowly with increasing thickness while the emitted light output will increase close to linearly. Eventually, the device will become thicker than a diffusion length when performance will start to deteriorate. The use of multiple junctions such as in the multilayer diode of FIG. 9 will allow device performance to be maintained, where one or more additional junctions are added to the device as shown. This approach will also be suited for both surface and edge emitting devices, particularly when material of low recombination lifetime is used, such as for the material doped with defects producing mid-gap states, as discussed in the following.

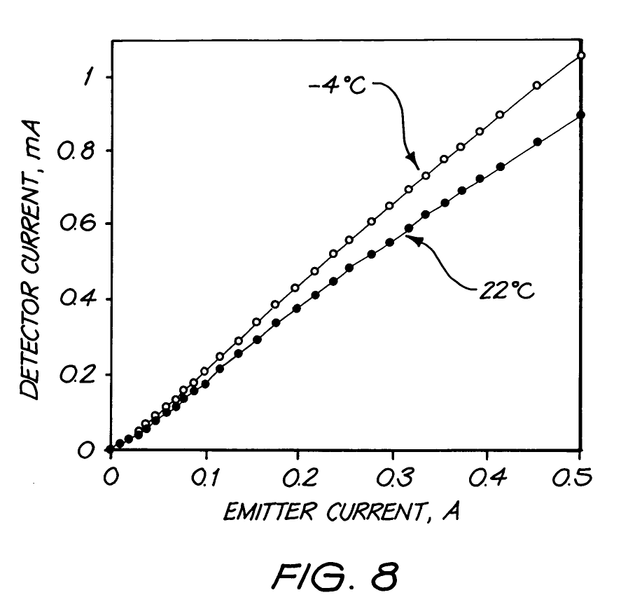

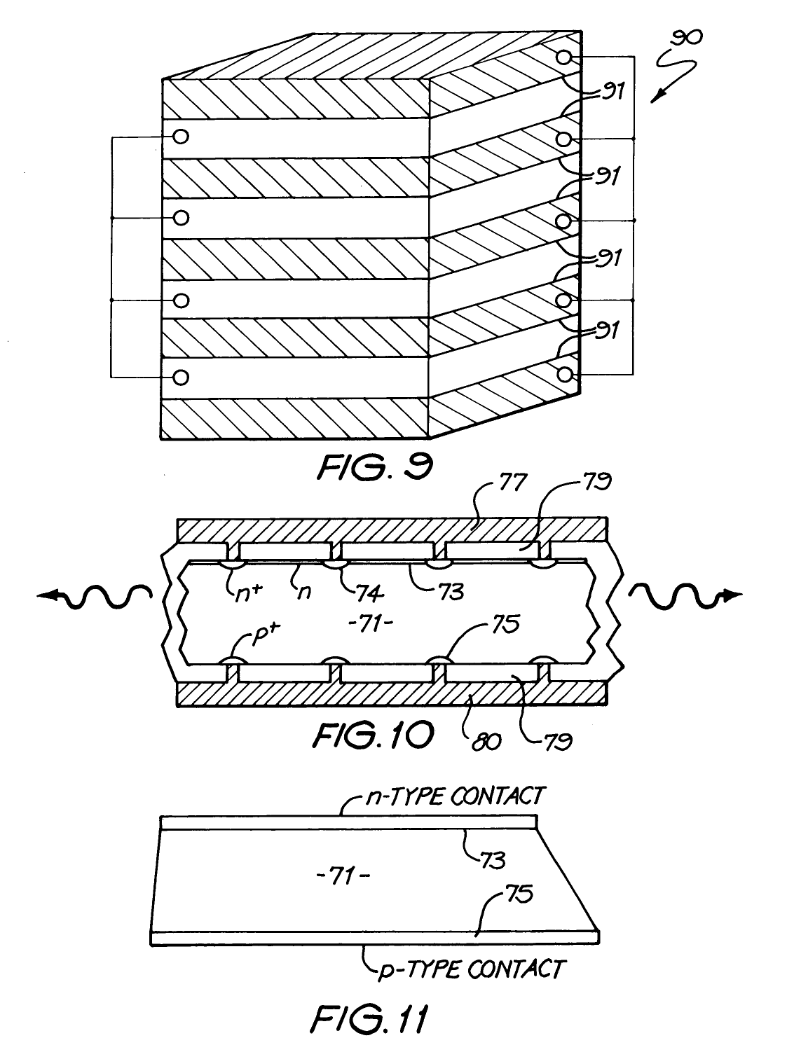

The second geometry of interest is the edge emitting structure as shown in FIG. 10. The effective thickness W of the device can be very large in this case limited only by the size of the starting substrate (say, 30 cm for a silicon wafer). Large W pushes the wavelength of peak emission to shorter wavelengths, where the photon occupational probability is higher. Hence, even though the dark saturation current density increases I₀₁ with the increased diode area, the emission efficiency remains high. Emission becomes dominated by processes involving two or more phonons. The edge emitter also allows flexibility with techniques for reducing I₀₁, also applicable to a varying extent to the surface emitting geometry. As well as the use of oxides and doping to control surface contributions to I₀₁, other surface passivation and contacting techniques such as those based on amorphous microcrystalline or polycrystalline silicon or their use in conjunction with oxides such as in the form of a thin-interfacial layer or as a matrix as in SIPOS (semi-insulating polycrystalline oxide semiconductor) are also suitable. Heavily doped amorphous silicon layers with an interfacial layer of lightly doped or intrinsic amorphous silicon are particularly well suited to this role.

Simple geometrical structures at either or both of the light emitting edges of this geometry can be used to enhance output in specific areas and directions as suggested in FIG. 11. By designing the device to be strongly absorbing for specific points and directors of incidence, very large pathlength is feasible. For example, the scheme of FIG. 14(a) is based on constraining light incident on the exit aperture of size D being trapped into the device for many passes along the device length. Eventually, the slight asymmetry in the scheme required to let the light into the device causes the light path to unravel. As the size D approaches zero, the number of possible passes and pathlength P approaches infinity.

For this and the other device designs reported, there is a limit on the useful value of P. The best that can be done is for P to be sufficiently large that the combined device absorptance at the desired emission wavelength approaches unity, with as little parasitic absorption as possible. The emission intensity at this wavelength ideally will then approach that for a black body at the diode temperature, exponentially enhanced by the diode voltage, but multiplied by the ratio of band to band absorption to total absorption. Since efforts to increase P will usually result in increased I₀₁, there will be an optimal design for maximum emission efficiency.

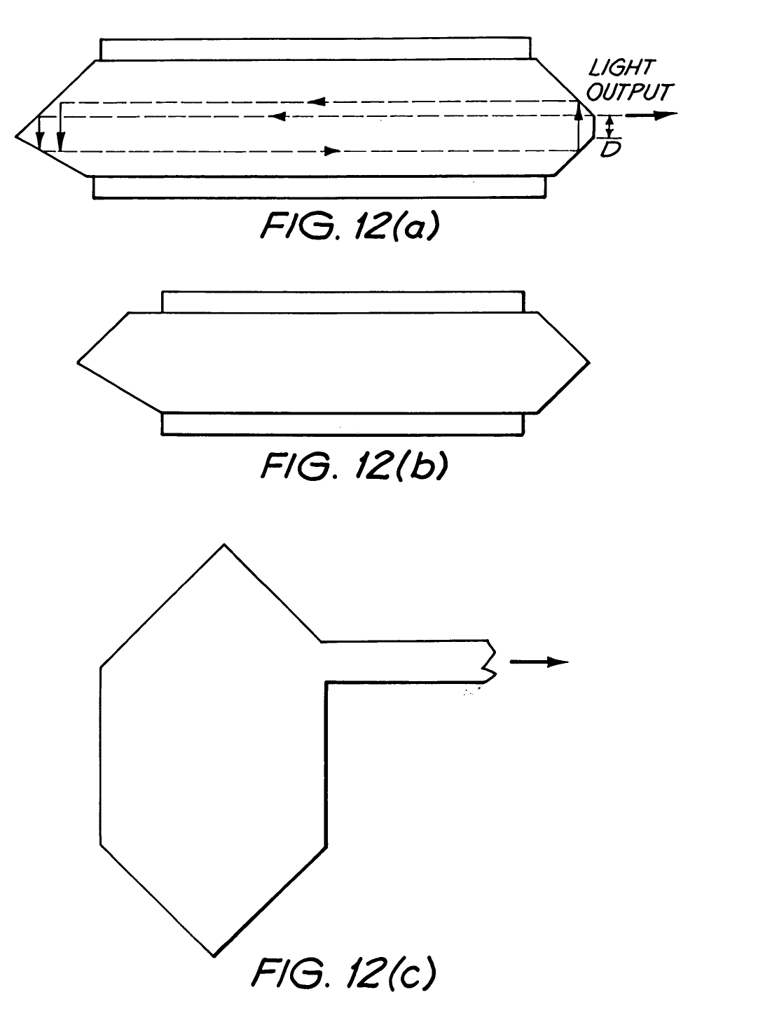

As shown in FIG. 12(b), edge bevels can also be used to enhance light emission in designated regions and directions of surface emitting devices. As shown in plan view in FIG. 12(c), the diode geometry itself can be used to implement similar pathlength enhancement schemes. This might be particularly useful when the diodes are incorporated into microchips as subsequently discussed and used on these chips or elsewhere to supply light for light guides. Although the principles involved have been demonstrated using schemes based on 45° bevels, it is a simple matter to deduce similar geometrical schemes to trap light as indicated.

Some control over the emission wavelength is possible by controlling the effective thickness of the diode by the techniques previously described. However, there is an interest in light emission at longer wavelengths than possibly by this approach, such as 1.55 micron wavelength for optical fibre communications. The introduction of defects that produce energy states in the semiconductor bandgap allows this to be achieved. The new approach allows a correspondingly large improvement in the emission efficiency of such devices.

The ideal properties of the defect is that carriers from the band that is closest in energy to the defect level energy make rapid transitions to and from the defect energy while transitions to and from the other band are relatively slow and radiatively efficient. This ensures that the occupancy of the defect is governed by the occupancy of the nearer band and that radiative emission to the other band will increase exponentially with voltage, as for band-to-band emission.

Introduction of the defect will increase recombination in the diode increasing I₀₁ and requiring changes in device design. One desirable consequence of this is that the decreased carrier lifetime will allow fast switching speeds. Features that are particularly important are the increase in the absorption pathlength as previously described and the reduction of competitive absorption processes, particularly free carrier absorption. These are minimised by keeping the area of metal contact small, the volume of diffused material low and the doping in the bulk regions low while using dielectrical displacement to reduce reflection from metallic connectors along the device surface.

The edge emitting structure will allow the largest pathlength enhancement factors and will be particularly appropriate for defected material. Devices will need to be thinner when defects are included due to the decreased carrier lifetimes. Suitable defects are those such as Ge from Group IV of the periodic table, which forms an alloy with silicon, reducing its bandgap, dopants from Groups III and V, particularly those such as indium and thallium that give rise to states relatively deeply into the bandgap, and defects that more tightly bind electrons such as rare earth metals such as Er, Yb and combinations thereof. Er has an absorption peak close to 1.55 microns. Combinations of rare earths can increase the efficiency of absorption processes. Defects such as dislocations are another possible source of emission.

Two partly compensating effects influence the emission efficiency of such low energy processes. One is that the photon state occupancy increases rapidly as the energy decreases as given by Eq.(3), helping to improve the efficiency. The other is the increased value of I₀₁ that decreases efficiency. Increasing the number of defects up to a certain level increases emission and I₀₁, so that efficiency is approximately constant over a range of defect combinations.

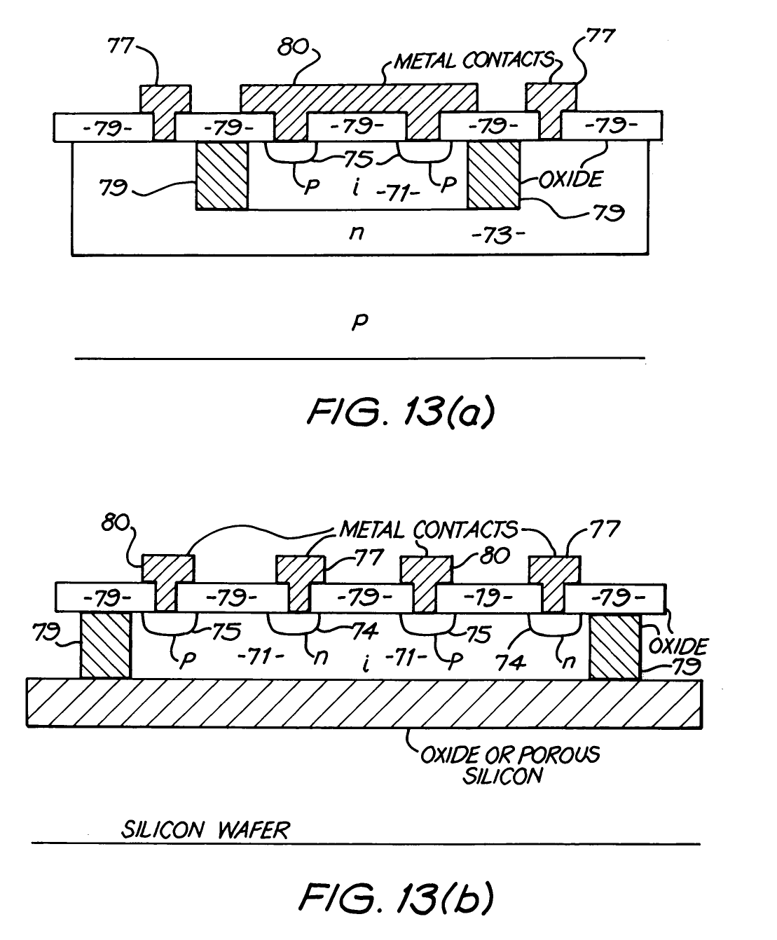

As well as the discrete devices previously discussed, the new devices are suitable for use in integrated circuits. This introduces additional complexities with contacting the rear of the device and with keeping reflectance from this surface high. This does not pose any problems for edge emitting devices, which can use pathlength enhancement schemes such as shown in FIG. 12(c) in plan view. In side view, relatively standard integrated circuit processing technologies would allow various possibilities such as shown in FIGS. 13(a) and (b).

The output can be fed into wave-guides made of silicon, silicon dioxide or other material. In the former case the waveguide can be made active itself by having it in the form of a diode as in FIG. 13(a) or (b), reducing the area required for implementing the scheme such as in FIG. 12(c), or removing the need for a dedicated diode area. The previous considerations apply to devices operating with band edge emission or with emission from defects.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A light emitting device with alterable emission characteristics, the device comprising:
a light emitting portion comprising a pn junction for emission of light by application of current to flow through the pn junction; and
means for applying an electric field across the light emitting portion by applying a voltage to one or more contacts that are electrically isolated from the pn junction in order to alter a light emission characteristic of the light emitting portion.

2 The light emitting device as claimed in claim 1 wherein the light emitting portion and pn junction comprise silicon.

3. The light emitting device as claimed in claim 2 wherein the light emitting portion and pn junction comprise crystalline silicon.

4. The light emitting device as claimed in claim 1 wherein the light emitting portion and pn junction comprise SiGe.

5. The light emitting device as claimed in claim 1, wherein the light emitting portion of the device comprises a thin layer which has a sufficiently small thickness to allow quantum confinement effects to occur.

6. The light emitting device as claimed in claim 5 wherein the thin layer comprises a quantum well.

7. The light emitting device as claimed in claim 5, wherein the layer has a thickness less than 20 nm.

8. The light emitting device as claimed in claim 7 wherein the layer has a thickness of substantially 2 nm.

9. The light emitting device as claimed in claim 1, wherein the light emitting portion of the device comprises a layer which has a thickness greater than a maximum thickness which can achieve quantum confined Stark effects.

10. The light emitting device as claimed in claim 1, wherein the means for applying an electric field across the light emitting portion is arranged such that the electric field is applied across the layer substantially normal to a plane defined by the layer.

11. The light emitting device as claimed in claim 1, wherein the device is integrated in an integrated circuit.

12. The light emitting device as claimed in claim 1, wherein the light emitting portion of the device is formed of a material having high excited carrier lifetimes.

13. The light emitting device as claimed in claim 1, wherein the means for applying the electric field across the light emitting portion is operable to repeatedly apply the electric field at a switching rate greater than substantially ten GHz.

14. The light emitting device as claimed in claim 1, wherein the light emitting device is a waveguide edge emitting device.

15. The light emitting device as claimed in claim 14 wherein the waveguide is formed by layers having a lower refractive index than the light emitting portion positioned either side of the light emitting portion, such that light generated within the light emitting portion travels within the light emitting portion to emerge laterally from the light emitting portion.

16. The light emitting device as claimed in claim 15, wherein the light emitting portion comprises silicon, and the layers having a lower refractive index comprise silicon oxide.

17. The light emitting device as claimed in claim 14, wherein the dimensions of the light emitting portion are smaller than a typical diffusion length of the material of the light emitting portion.

18. The light emitting device as claimed in claim 14, wherein a thickness of the light emitting portion is chosen in order to optimise the performance of the waveguide at a desired frequency of emission.

19. The light emitting device as claimed in claim 1, wherein the light emitting device is a surface emitting device.

20. The light emitting device as claimed in claim 19 wherein the surface emitting device is in bulk form.

21. The light emitting device as claimed in claim 19 wherein the surface emitting device is in integrated form.

22. The light emitting device as claimed in claim 19, further comprising transparent layers between the light emitting portion of the device and the region into which the light is to be emitted.

23. The light emitting device as claimed in claim 22, wherein the means for applying the electric field comprises a transparent electrode positioned over the light emitting portion, and wherein a transparent dielectric is positioned between the transparent electrode and the light emitting portion.

24. The light emitting device as claimed in claim 19, wherein the means for applying the electric field comprises an electrode positioned over the light emitting portion in a grid pattern for limiting shading, and wherein a transparent dielectric is positioned between the electrode and the light emitting portion.

25. The light emitting device as claimed in claim 1, wherein the light emitting portion comprises a layer, wherein contacts are provided for biasing the p and n regions of the pn junction, and wherein said contacts are positioned at opposed lateral edges of the layer.

26. The light emitting device as claimed in claim 25, wherein a heavily doped p+ region is provided close to the p contact.

27. The light emitting device as claimed in claim 25, wherein a region of p+ or p+/intrinsic amorphous silicon is provided close to the p contact.

28. The light emitting device as claimed in claim 25, wherein a heavily doped n+ region is provided close to the n contact.

29. The light emitting device as claimed in claim 25, wherein a region of n+ or n+/intrinsic amorphous silicon is provided close to the n contact.

30. The light emitting device as claimed in claim 25, wherein said contacts contact the layer only at discrete spaced positions along the lateral edges of the layer.

31. The light emitting device as claimed in claim 25, wherein the surfaces of the layer of the light emitting portion are passivated in regions where the contacts do not contact the layer.

32. The light emitting device as claimed in claim 31, wherein the surfaces of the layer of the light emitting portion are passivated by a silicon oxide layer formed over the surfaces.

33. The light emitting device as claimed in claim 31, wherein the surfaces of the layer of the light emitting portion are passivated by a polycrystalline layer.

34. The light emitting device as claimed in claim 31, wherein the surfaces of the layer of the light emitting portion are passivated by a microcrystalline layer.

35. The light emitting device as claimed in claim 31, wherein the surfaces of the layer of the light emitting portion are passivated by an amorphous silicon layer.

36. The light emitting device as claimed in claim 1, wherein a layer below the light emitting portion is formed of a material having a lower refractive index than the light emitting portion, so as to internally reflect light.

37. The light emitting device as claimed in claim 36, wherein the layer below the light emitting portion comprises a dielectric/metal reflecting layer combination.

38. The light emitting device as claimed in claim 1, wherein an anti-reflective coating is provided over a surface from which the device emits light.

39. The light emitting device as claimed in claim 1, wherein at least one dimension of the light emitting portion is a significant fraction of a diffusion length of the material of the light emitting portion.

40. The light emitting device as claimed in claim 1, comprising a plurality of light emitting portions.

41. The light emitting device of claim 40 wherein the light emitting device comprises alternating layers of dielectrics and light emitting portions.

42. The light emitting device as claimed in claim 1, wherein the light emitting portion comprises a bulk region being only relatively lightly doped, and comprises only relatively small amounts of relatively heavily doped silicon.

43. The light emitting device as claimed in claim 1, wherein the light emitting portion comprises a bulk region with introduced defects for enhancing sub-bandgap absorption.

44. The light emitting device as claimed in claim 43, wherein the introduced defects comprise Ge.

45. The light emitting device as claimed in claim 43, wherein the introduced defects comprise dopants from Groups III or V of the periodic table.

46. The light emitting device as claimed in claim 43, wherein the introduced defects give rise to states relatively deeply within the bandgap.

47. The light emitting device as claimed in claim 46, wherein the introduced defects comprise indium dopants.

48. The light emitting device as claimed in claim 46, wherein the introduced defects comprise thallium dopants.

49. The light emitting device as claimed in claim 43, wherein the introduced defects more tightly bind electrons.

50. The light emitting device as claimed in claim 49, wherein the introduced defects comprise rare earth metals.

51. The light emitting device as claimed in claim 50, wherein the introduced defects comprise Er or Yb.

52. The light emitting device as claimed in claim 43, wherein the introduced defects comprise dislocations.

53. The light emitting device as claimed in claim 1, wherein an emitting surface of the device is of a geometry which directs emissions in a predetermined direction.

54. The light emitting surface as claimed in claim 53, wherein the emitting surface of the device is bevelled.

55. The light emitting device as claimed in claim 53, wherein the device comprises a periodic structure to produce a diffraction effect.

56. The light emitting device as claimed in claim 1, wherein the emitting surface comprises a textured geometry comprising (111) equivalent crystallographic planes present in a (100) oriented wafer surface plane.

57. The light emitting device as claimed in claim 53, wherein the emitting surface is textured by anisotropic etching.

58. A method of altering light emissions from a light emitting diode, the method comprising the step of:
applying a current across a pn junction of the light emitting diode to cause the light emitting diode to emit light; and
applying an electric field across the light emitting diode portion by applying a voltage to one or more contacts that are electrically isolated from the pn junction so as to alter light emission characteristics of the light emitting diode.

59. The method as claimed in claim 58 wherein the light emitting diode comprises silicon.

60. The method as claimed in claim 59 wherein the light emitting diode comprises crystalline silicon.

61. The method as claimed in claim 58 wherein the light emitting diode comprises SiGe.

62. The method as claimed in claim 58, wherein the light emitting diode comprises a thin layer which has a sufficiently small thickness to allow quantum confinement effects to occur, such that application of the electric field causes the quantum confined Stark effect to occur.

63. The method as claimed in claim 62 wherein the thin layer comprises a quantum well.

64. The method as claimed in claim 58, wherein the step of applying the electric field across the light emitting diode comprises applying the electric field across the diode substantially normal to a plane defined by a layer of the diode.

65. The method as claimed in claim 58, wherein the diode is integrated in an integrated circuit.

66. The method as claimed in claim 58, wherein the step of applying the electric field across the light emitting diode comprises repeatedly applying the electric field at a switching rate greater than substantially ten GHz.

67. The method as claimed in claim 58, wherein the light emitting diode is a waveguide edge emitting device.

68. The method as claimed in claim 58, wherein the step of applying the electric field serves to encode data on a light signal produced by the diode, for transmission through an optical transmission system.

69. A silicon light emitting device comprising an emitting surface having geometry for directing emissions in a predetermined direction.

70. The silicon light emitting device as claimed in claim 69, wherein the emitting surface geometry is implemented by bevelling of the emitting surface.

71. The silicon light emitting device as claimed in claim 69, wherein the emitting surface geometry is implemented by a periodic structure which produces a diffraction effect.

72. A silicon light emitting device with surface geometry adapted to control the passage of light in the device so as to improve absorption.

73. The silicon light emitting device as claimed in claim 72 wherein the surface geometry is created by texturing one or more surfaces of the device.

74. The silicon light emitting device as claimed in claim 73 wherein the textured surface geometry comprises (111) equivalent crystallographic planes present in a (100) orientated wafer surface plane, exposed by anisotropic etching.

75. A method of design of a silicon light emitting diode, comprising the step of designing a silicon device having high light absorption, for reverse operation as a light emitting diode.

76. A light modulator comprising:
a layer of silicon, to be positioned in the path of light to be modulated; and
means to apply an electric field across the silicon layer so as to alter the bandgap of the silicon layer, thus controlling whether light is absorbed by the silicon layer or transmitted through the silicon layer.

77. The modulator of claim 76, wherein the silicon layer is of a sufficiently small thickness to exhibit quantum confinement effects, such that application of the electric field induces bandgap alterations by way of the quantum confined Stark effect.

78. The modulator of claim 76 wherein the silicon layer is of a thickness to exhibit Franz-Keldysh effects upon application of the electric field.

79. The modulator of claim 76 wherein the modulator is in integrated form on a silicon integrated circuit.

80. The modulator of claim 76 wherein the modulator is in bulk form on a silicon integrated circuit.

81. A method of modulating light, the method comprising the steps of:
positioning a layer of silicon in the path of the light; and
applying an electric field across the thin silicon layer so as to alter the bandgap of the silicon layer, thus controlling whether light is absorbed by the silicon layer or transmitted through the silicon layer.

82. The method of claim 81, wherein the silicon layer is of a sufficiently small thickness to exhibit quantum confinement effects, such that application of the electric field induces bandgap alterations by way of the quantum confined Stark effect.

83. The method of claim 81 wherein the silicon layer is of a thickness to exhibit Franz-Keldysh effects upon application of the electric field.

84. The method of claim 81, wherein the step of applying the electric field comprises repeatedly applying the electric field at a switching rate greater than substantially 10 GHz.

85. The method of claim 81, wherein the step of applying the electric field causes modulation of data onto a light signal for transmission in an optical transmission system.
